(19) United States
(12) Patent Application Publication
(10) Pub. No.: US 2006/0220005 A1
(43) Pub. Date: Oct. 5, 2006

(54) Logic gate with a potential-free gate electrode for organic integrated circuits

(76) Inventors: Walter Fix, Nurnberg (DE); Wolfram Glauert, Reutlingen (DE); Andreas Ullmann, Zirndorf (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/562,869

(22) PCT Filed: Jun. 30, 2004
(86) PCT No.: PCT/DE04/01376

§ 371 Date: Apr. 7, 2006

(30) Foreign Application Priority Data
Jul. 3, 2003 (DE) 103 30 064.3

(51) Int. Cl. H01L 29/08

(52) U.S. Cl. 257/40

(57) ABSTRACT

The invention relates to an organic logic gate comprising at least one charging field effect transistor (charging FET) and at least one switching field effect transistor (switching FET), the charging FET having at least one gate electrode, a source electrode and a drain electrode, the gate electrode of the charging FET being potential-free.

The technical field of the invention relates to organic logic gates such as, for example, ANDs, NANDs, NORs and the like. The present invention furthermore relates to the problem of the switching times and the switching stability of organic logic gates.

This problem has hitherto only partly been solved by connecting the gate electrode of the charging FET in the logic gate to the supply voltage, whereby fast logic gates can be provided. However, this solution requires a high supply voltage of above 20 V. This measure for improving the switching behavior of organic logic gates is described, for example in the article “Fast polymer integrated circuits” in Applied Physics Letters, Issue 81, page 1735 (2002).

Another approach is described, for example in the article “High performance all-polymer integrated circuits” in Applied Physics Letters, Issue 77, page 1487 (2000). This article describes that the gate electrode of the charging FET can be connected to the output of the inverter or of the logic gate. This results in circuits which can be operated with low voltages but have the disadvantage that they are very slow.

No organic logic gate circuits have been realized hitherto which can switch rapidly and stably even with low supply voltages.

For reasons of energy efficiency it is desirable to lower the supply voltages of organic logic gate circuits even during fast operation of organic circuits, without impairing the switching stability in the process.

It is furthermore desirable to reduce the switching times of organic logic gate circuits without having to increase the supply voltage.

It is desirable, moreover, to increase the switching stability of organic circuits without impairing the switching times or increasing the supply voltages in the process.

In accordance with a first aspect, the invention provides an organic logic gate comprising at least one charging FET and at least one switching FET. In this case, the (at least one) charging FET has at least one gate electrode, a source electrode and a drain electrode. In this case, the organic logic gate according to the invention is characterized in that the gate electrode of the charging FET is potential-free.

By using a potential-free electrode it is possible to construct a rapidly and at the same time stably switching organic logic gate.

In one advantageous embodiment of the organic logic gate, the gate electrode of the charging FET is capacitively coupled to a source electrode of the charging FET. In another advantageous refinement of the organic logic gate, the drain electrode of the charging FET is capacitively coupled to a gate electrode of the charging FET. It is thus possible, with a relatively low outlay, for the gate electrode to be coupled to one of the other terminals of the charging FET in order to improve the switching behavior of the logic gate. The capacitive coupling between the gate electrode and one of the other terminals of the FET makes it possible, given a suitable design of the charging FET and the coupling capacitance, to improve the switching properties of the logic gate. The present invention makes it possible for organic logic gates to function or to switch rapidly and stably even at low supply voltages (below 10 V).

In a further advantageous refinement of the invention, the capacitive coupling is achieved by means of the gate electrode overlapping the source electrode of the charging FET. In another advantageous refinement of the invention, the capacitive coupling is achieved by means of the gate electrode overlapping the drain electrode of the charging FET. The embodiment of a capacitive coupling can be obtained by means of a slightly increased outlay on circuit design, without additional work or process steps having to be introduced during production. The space requirement of a logic gate may increase as a result of the space requirement of the capacitive coupling or of the coupling capacitor.

Another advantageous refinement of an organic logic gate is constructed without plated-through holes. In the case of a capacitive coupling between gate electrode and source or drain electrode of a charging FET, it is possible to dispense with a direct electrical coupling between the two electrodes. In the two cases above, it is possible to completely dispense with a through-plating of the insulation layer between gate electrode and drain or source electrode. The production process can be simplified as a result. Moreover, the yield can be increased if fewer or no defective plated-through holes occur.

In a further advantageous refinement of the present invention, the gate electrode of the charging FET is resistively coupled to the drain electrode and/or the source electrode of the charging FET. In the simplest case, this gives rise to a direct electrical coupling between the (at least one) gate electrode and one of the terminals of the charging FET. The direct electrical coupling may be realized by plated-through holes through the insulation layer of the FET or by interconnects which go beyond a region of the (possibly printed-on) insulator layer and form a contact layer there. This design has a further advantage since the capacitance and the resistance of the resistive coupling can be set to a suitable choice of the length, the width and also the coverage of the interconnects as far as an edge region of the insulator layer.

In another preferred embodiment of the invention, the gate electrode of the charging FET, in parallel with the capacitive coupling, is resistively coupled to the source electrode of the charging FET. In another advantageous embodiment of the present invention, the gate electrode of the charging FET, in parallel with the capacitive coupling, is resistively coupled to the drain electrode of the charging FET. The combination of a capacitance with a resistance results in the construction of an RC element which impresses on the coupling of the charging FET a time response which may positively influence the switching time of the charging FET. The inherent capacitance of the FET must be taken into account, however, in the design of the RC element.

The invention is described below with reference to the accompanying drawing, in which:

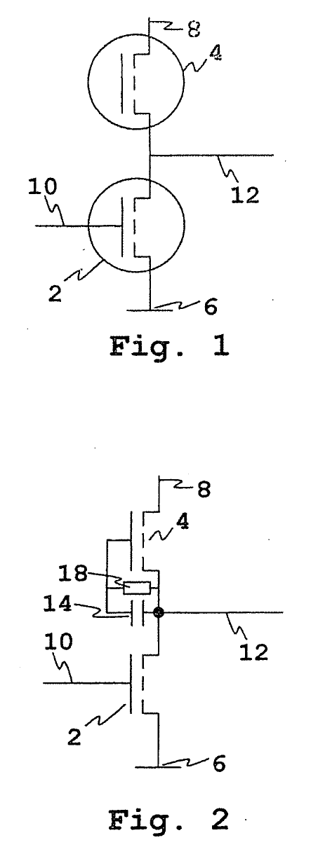

FIG. 1 illustrates an embodiment of a logic gate with a charging FET with a potential-free gate electrode,

FIG. 2 illustrates an embodiment of an inverter with a charging FET with a gate electrode which is capacitively coupled to the output,

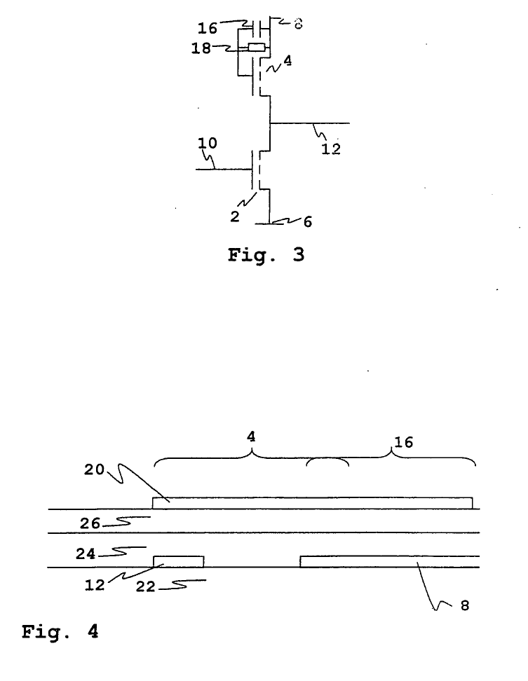

FIG. 3 illustrates an embodiment of an inverter with a charging FET and a gate electrode which is capacitively coupled to the output, and

FIG. 4 illustrates a sectional view through a charging FET in accordance with one embodiment of the present invention.

Identical reference symbols have been used for identical or similar elements both in the description and in the figures.

FIG. 1 illustrates an embodiment of a logic gate with a charging FET with a potential-free gate electrode. The logic gate chosen is embodied here as an inverter since the inverter as the simplest component can illustrate the advantages of the present invention the most clearly. FIG. 1 shows the connection in series of two transistors 2 and 4 to form an inverter. In this case, the transistor 2 is the switching transistor and the transistor 4 is the charging transistor. In FIG. 1, the source electrode 6 of the switching FET 2 is grounded. The drain electrode is connected to the output 12 of the inverter. The gate electrode 10 of the switching transistor 2 forms the input of the inverter. The source and drain electrodes of the charging transistor 4 connect the output 12 of the inverter to the supply voltage 8.

FIG. 2 illustrates an embodiment of an inverter with a charging FET with a gate electrode which is capacitively coupled to the output. In FIG. 2, the gate electrode of the charging FET 4 is coupled to the output 12 by means of the capacitance 14. The capacitance 14 may be implemented for example by the gate electrode overlapping the source or drain electrode. The capacitive coupling by the capacitor 14 may be supplemented, as illustrated, by connection in parallel with a resistor 18.

FIG. 3 illustrates an embodiment of an inverter with a charging FET with a gate electrode which is capacitively coupled to the output. In FIG. 3 the gate electrode of the charging FET 4 is coupled to the supply voltage 8 by means of the capacitance 16. The capacitance 16 may be implemented for example by the gate electrode overlapping the source or drain electrode. The capacitive coupling by the capacitor 16 may be supplemented, as illustrated by a resistor 18 connected in parallel.

All other possible logic gates such as, for example, AND, NAND, OR, NOR, XOR and the like can be implemented from the inverter circuit by addition of (switching) FETs connected in series or in parallel and are therefore not presented explicitly.

FIG. 4 illustrates a cross section through a charging FET in accordance with the present invention. The charging FET is applied on a carrier material or on a substrate 22. The substrate 22 may comprise, for example, glass, plastic, crystal or a similar material.

Two electrodes 8 and 12 of the charging FET are applied on the substrate 22. One of the electrodes 8, 12 is the source electrode and one electrode is the drain electrode. A circuit in accordance with FIG. 2 or FIG. 3 results depending on the choice of electrodes.

The two electrodes 8, 12 are connected by a semiconductor layer 24. An insulator layer 26 is arranged above the semiconductor layer 24. The gate electrode 20 is arranged above the insulator layer 24. In this case, the region 4 essentially defines the charging transistor and the region 16 essentially defines the region of the capacitive coupling between the gate electrode 20 and the electrode 8. With the reference symbols illustrated, the section illustrates one possible implementation of the charging FET of the inverter circuit from FIG. 3. With a different assignment of the reference symbols, the section illustrated can also be applied to the inverter circuit from FIG. 2.

The resistors 18 illustrated in FIGS. 2 and 3 are not illustrated in FIG. 4 and can be realized for example by plated-through holes through the layer 26 between the electrodes 8 and 20.

It is clear that logic gate circuits with more than one charging FET, that is to say for example combinations e.g. of parallel or series circuits of charging FETS in accordance with FIG. 2 and FIG. 3, also come under the present invention.

It is furthermore clear that the present invention can also be applied to tristate logic gates. It is clear that the terminals 6 and 8 can also be interchanged.

1. An organic logic gate comprising:
a circuit having an output and comprising at least one charging field effect transistor (charging FET) having source, drain and gate electrodes and at least one switching field effect transistor (switching FET) having at least one gate electrode, a source electrode and a drain electrode, the drain-source electrodes of the charging and switching transistors being arranged to be coupled in series between a voltage source and a reference potential such that the gate electrode of the charging FET is not connected via an electrical line directly to the voltage source, to the reference potential or to the output.

2. The organic logic gate as claimed in claim 1 wherein the gate electrode of the charging FET is capacitively coupled to the source electrode of the charging FET.

3. The organic logic gate as claimed in claim 2 wherein the capacitive coupling is achieved by the gate electrode of the charging FET overlapping the source electrode of the charging FET.

4. The organic logic gate as claimed in claim 1 wherein the gate electrode of the charging FET is resistively coupled to the source electrode of the charging FET.

5. The organic logic gate as claimed in claim 1 wherein the gate electrode of the charging FET is capacitively coupled to the drain electrode of the charging FET.

6. The organic logic gate as claimed in claim 5 wherein the capacitive coupling is achieved by the drain electrode overlapping the gate electrode of the charging FET.

7. The organic logic gate as claimed in claim 1 wherein the gate electrode of the charging FET is resistively coupled to the drain electrode of the charging FET.

8. The organic logic gate as claimed in claim 1 wherein the organic logic gate is constructed without plated-through holes.
